(19) United States
(12) Patent Application Publication
(10) Pub. No.: US 2025/0253214 A1
(43) Pub. Date: Aug. 7, 2025

(54) PACKAGE STRUCTURE AND METHOD OF FORMING THEREOF

(71) Applicant: CHINGIS TECHNOLOGY CORPORATION, Hsinchu City (TW)

(72) Inventor: Cheng-Fu YU, Hsinchu City (TW)

(21) Appl. No.: 18/665,681

(22) Filed: May 16, 2024

(30) Foreign Application Priority Data
Feb. 6, 2024 (TW) 113104606

(51) Int. Cl. H01L 23/495; H01L 21/56; H01L 23/00; H01L 25/18

(52) U.S. Cl. CPC H01L 23/49575; H01L 21/561; H01L 21/565; H01L 23/49506; H01L 24/97; H01L 25/18; H01L 2224/97

(57) ABSTRACT

A method of forming a package structure includes forming a plurality of grooves on a surface of a leadframe, disposing a metal paste in the grooves, heating the metal paste to form a solderable portion in each of the grooves and cutting a plurality of cutting streets of the leadframe to form the package structure. The leadframe includes a plurality of leads, and the grooves are disposed on a side of each of the leads. The solderable portion covers the side of each of the leads.

### RELATED APPLICATIONS

This application claims priority to Taiwan Application Serial Number 113104606, filed Feb. 6, 2024, which are herein incorporated by reference.

### BACKGROUND

### Technical Field

The present disclosure relates to a package structure and a method of forming thereof. More particularly, the present disclosure relates to a package structure and a method of forming thereof which can enhance the side wettable area.

### Description of Related Art

In general, the copper-exposing surfaces of the quad flat no leads (QFN) structure are formed after the cutting process, so that the solderable area of the lateral of each of the leads is insufficient, and the solderable strength of subsequent disposition on the circuit board is insufficient, which leads the problem of reducing the lifetime of disposing on the circuit board. In particular, the solder fatigue or the solder crack is usually caused on the lateral and the bottom of each of the leads so as to form the package defects. Furthermore, some package manufacturers cannot set the plating line up for the plating process due to the environmental issues, and the aforementioned problem is hardly solved until now.

Therefore, a package structure and a method of forming thereof, which simultaneously obtain the solderable stability, enhance the board-level lifetime and save the plating process, needs to be developed.

### SUMMARY

According to one aspect of the present disclosure, a method of forming a package structure includes forming a plurality of grooves on a surface of a leadframe, disposing a metal paste in the grooves, heating the metal paste to form a solderable portion in each of the grooves and cutting a plurality of cutting streets of the leadframe to form the package structure. The leadframe includes a plurality of leads, and the grooves are disposed on a side of each of the leads. The solderable portion covers the side of each of the leads.

According to one aspect of the present disclosure, a method of forming a package structure includes forming at least one groove on a surface of a leadframe, disposing a metal paste in the groove, heating the metal paste to form a solderable portion in the groove and cutting a plurality of cutting streets of the leadframe to form the package structure. The leadframe includes a plurality of leads, and the groove is disposed on a side of at least one of the leads. The solderable portion covers the side of at least one of the leads.

According to one aspect of the present disclosure, a package structure includes a leadframe, a semiconductor die, a plastic package material and a solderable portion. The leadframe includes a die pad and a plurality of leads. The leads are disposed around the die pad. The semiconductor die is disposed on the die pad of the leadframe. The plastic package material is disposed on the leadframe. The solderable portion covers a surface of at least one of the leads.

### BRIEF DESCRIPTION OF THE DRAWINGS

FIG. 1 is a step flow chart of a method of forming a package structure according to the 1st example of the present disclosure.

FIG. 2 is a schematic view of the steps according to the 1st example in FIG. 1.

FIG. 3 is a cross-sectional schematic view of a leadframe along line 3-3 in FIG. 2.

FIG. 4 is a schematic view of the step according to the 1st example in FIG. 1.

FIG. 5 is a cross-sectional schematic view of the leadframe along line 5-5 in FIG. 4.

FIG. 6 is a schematic view of the step according to the 1st example in FIG. 1.

FIG. 7 is a cross-sectional schematic view of the leadframe along line 7-7 in FIG. 6.

FIG. 8 is a schematic view of the step according to the 1st example in FIG. 1.

FIG. 9 is a cross-sectional schematic view of the package structure along line 9-9 in FIG. 8.

FIG. 10 is a front view of the package structure according to the 1st example in FIG. 1.

FIG. 11 is a back view of the package structure according to the 1st example in FIG. 1.

FIG. 12 is a partial schematic view of the package structure according to the 1st example in FIG. 1.

FIG. 13 is a side view of the package structure according to the 1st example in FIG. 1.

FIG. 14 is a side view of the package structure after soldering according to the 1st example in FIG. 1.

FIG. 15 is a partial side view of the package structure after soldering according to the 1st example in FIG. 14.

FIG. 16 is a step flow chart of a method of forming a package structure according to the 2nd example of the present disclosure.

FIG. 17 is a schematic view of the steps according to the 2nd example in FIG. 16.

FIG. 18 is a cross-sectional schematic view of the leadframe along line 18-18 in FIG. 17.

FIG. 19 is a schematic view of the step according to the 2nd example in FIG. 16.

FIG. 20 is a cross-sectional schematic view of the leadframe along line 20-20 in FIG. 19.

FIG. 21 is a schematic view of the step according to the 2nd example in FIG. 16.

FIG. 22 is a cross-sectional schematic view of the leadframe along line 22-22 in FIG. 21.

FIG. 23 is a schematic view of the step according to the 2nd example in FIG. 16.

FIG. 24 is a cross-sectional schematic view of the package structure along line 24-24 in FIG. 23.

FIG. 25 is a front view of the package structure according to the 2nd example in FIG. 16.

FIG. 26 is a back view of the package structure according to the 2nd example in FIG. 16.

FIG. 27 is a partial schematic view of the package structure according to the 2nd example in FIG. 16.

FIG. 28 is a side view of the package structure according to the 2nd example in FIG. 16.

FIG. 29 is a side view of the package structure after soldering according to the 2nd example in FIG. 16.

FIG. 30 is a partial side view of the package structure after soldering according to the 2nd example in FIG. 29.

FIG. 31 is a step flow chart of a method of forming a package structure according to the 3rd example of the present disclosure.

FIG. 32 is a schematic view of the steps according to the 3rd example in FIG. 31.

FIG. 33 is a cross-sectional schematic view of the leadframe along line 33-33 in FIG. 32.

FIG. 34 is a schematic view of the step according to the 3rd example in FIG. 31.

FIG. 35 is a cross-sectional schematic view of the leadframe along line 35-35 in FIG. 34.

FIG. 36 is a schematic view of the steps according to the 3rd example in FIG. 31.

FIG. 37 is a cross-sectional schematic view of the package structure along line 37-37 in FIG. 36.

FIG. 38 is a front view of the package structure according to the 3rd example in FIG. 31.

FIG. 39 is a back view of the package structure according to the 3rd example in FIG. 31.

FIG. 40 is a partial schematic view of the package structure according to the 3rd example in FIG. 31.

FIG. 41 is a partial schematic view of a method of forming a package structure according to the 4th example of the present disclosure.

FIG. 42 is a cross-sectional schematic view of a leadframe along line 42-42 in FIG. 41.

FIG. 43 is a front view of the package structure according to the 4th example in FIG. 41.

FIG. 44 is a back view of the package structure according to the 4th example in FIG. 41.

FIG. 45 is a partial schematic view of the package structure according to the 4th example in FIG. 41.

FIG. 46 is a partial schematic view of a method of forming a package structure according to the 5th example of the present disclosure.

FIG. 47 is a cross-sectional schematic view of a leadframe along line 47-47 in FIG. 46.

FIG. 48 is another partial schematic view of the method of the package structure according to the 5th example in FIG. 46.

FIG. 49 is a cross-sectional schematic view of the leadframe along line 49-49 in FIG. 48.

FIG. 50 is a front view of the package structure according to the 5th example in FIG. 46.

FIG. 51 is a back view of the package structure according to the 5th example in FIG. 46.

FIG. 52 is a partial schematic view of the package structure according to the 5th example in FIG. 46.

### DETAILED DESCRIPTION

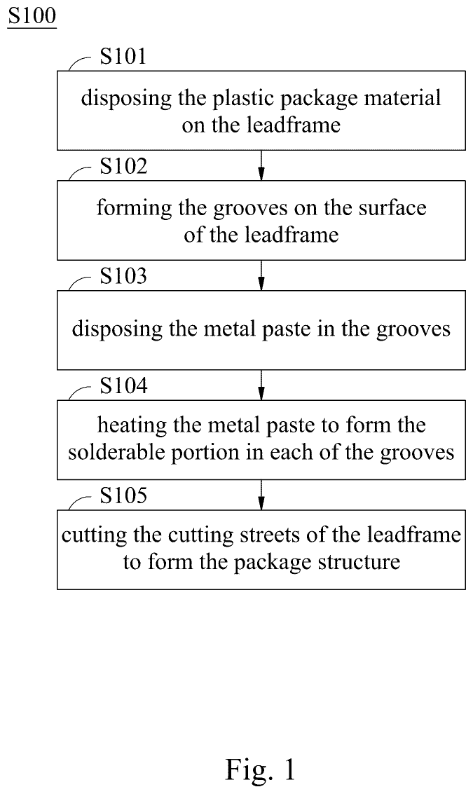

FIG. 1 is a step flow chart of a method of forming a package structure S100 according to the 1st example of the present disclosure. In FIG. 1, the method of the package structure S100 includes steps S101, S102, S103, S104, S105.

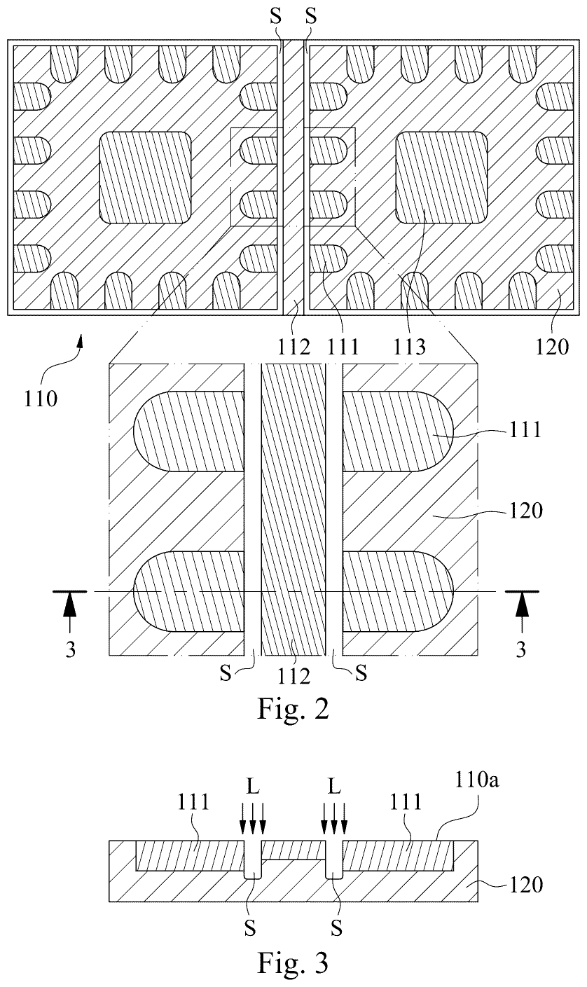

FIG. 2 is a schematic view of the steps S101, S102 according to the 1st example in FIG. 1. FIG. 3 is a cross-sectional schematic view of a leadframe 110 along line 3-3 in FIG. 2. In FIGS. 1 to 3, the step S101 includes disposing a plastic package material 120 on the leadframe 110, and the step S102 includes forming a plurality of grooves S on a surface 110a of the leadframe 110, wherein the leadframe 110 includes a plurality of leads 111 and a plurality of cutting streets 112, and the grooves S are disposed on a side of each of the leads 111. In particular, the surface 110a of the leadframe 110 is a lower surface of the leadframe 110 without covering via the plastic package material 120.

Moreover, the grooves S are formed on the surface 110a of the leadframe 110 by removing a portion of the leadframe 110 via a laser beam L during the step S102, the grooves S are disposed between each of the leads 111 and each of the cutting streets 112, and the grooves S are connected to each other, so that a continue groove is formed around every unit area of the leadframe 110, wherein every unit area of the leadframe 110 is a complete area surrounding a periphery of the die pad 113 via the leads 111, but the present disclosure is not limited thereto. It should be mentioned that the method of forming the package structure S100 can include a step including disposing a semiconductor die (not shown) on the die pad 113 of the leadframe 110 before the step S101.

According to the 1st example, a width of each of the grooves S can be 0.1 mm to 10 mm, but the present disclosure is not limited thereto.

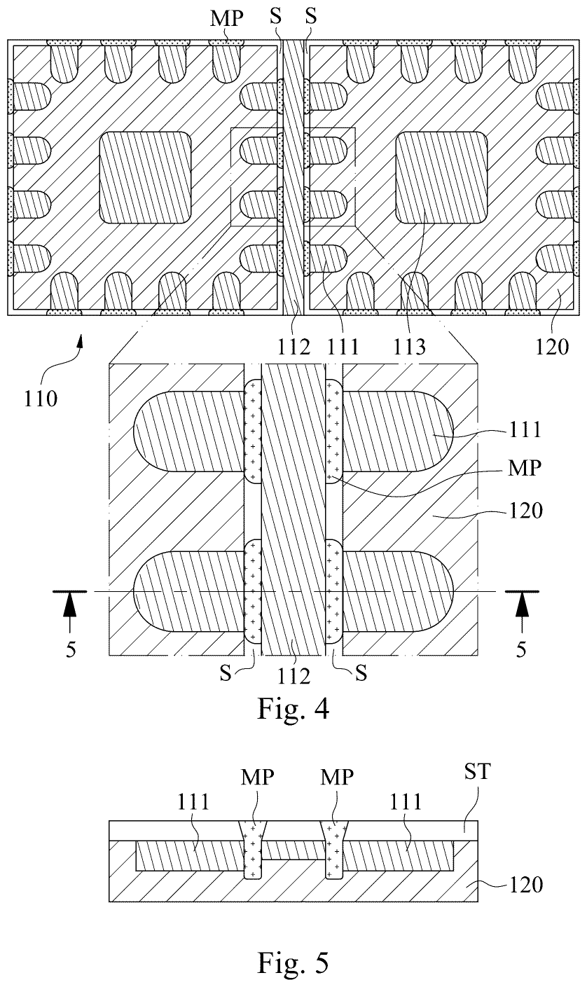

FIG. 4 is a schematic view of the step S103 according to the 1st example in FIG. 1. FIG. 5 is a cross-sectional schematic view of the leadframe 110 along line 5-5 in FIG. 4. In FIGS. 1, 4 and 5, the step S103 includes disposing a metal paste MP in the grooves S, wherein the metal paste MP can be disposed in the grooves S via a mold ST. In particular, the metal paste MP can be accurately disposed in the grooves S corresponding to a side of each of the leads 111 by printing via a plurality of openings of the mold ST, and the metal paste MP entirely covers a surface of each of the leads 111, wherein the metal paste MP can include tin, and the metal paste MP can be a high melting point metal paste so as to avoid melting in the following processes.

It should be mentioned that the metal paste MP can be further disposed on a surface of the die pad 113 and a bottom surface of each of the leads 111, wherein the surface of the die pad 113, the bottom surface of each of the leads 111 and the surface 110a of the leadframe 110 are located on the same side. Therefore, the connecting strength during the following disposition on the circuit can be enhanced, so that the board level reliability can be promoted, and the plating process can be further reduced, so that the problem, which the plating line due to the environmental issues cannot be set to process the plating process, can be solved.

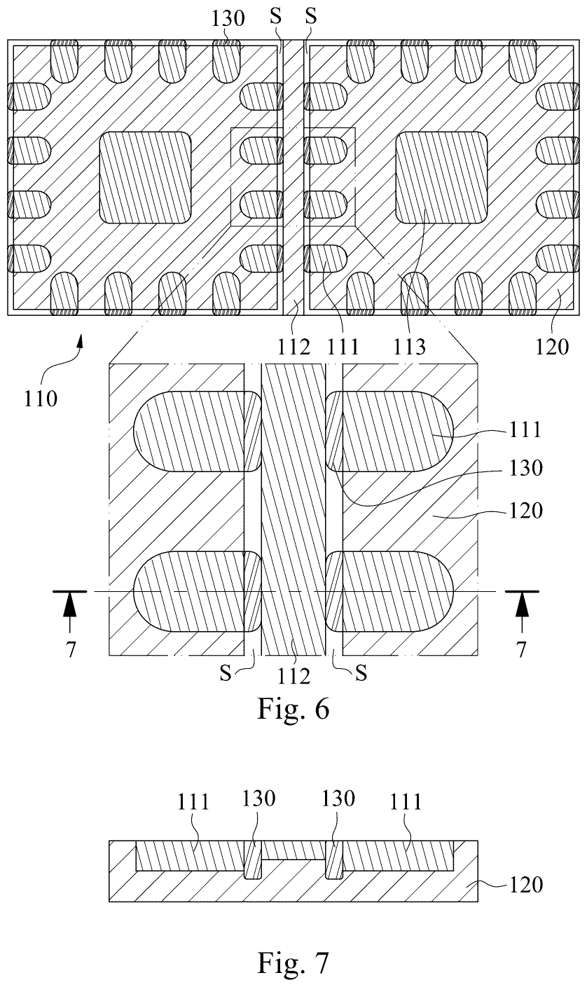

FIG. 6 is a schematic view of the step S104 according to the 1st example in FIG. 1. FIG. 7 is a cross-sectional schematic view of the leadframe 110 along line 7-7 in FIG. 6. In FIGS. 1, 6 and 7, the step S104 includes heating the metal paste MP to form a solderable portion 130 in each of the grooves S, and the solderable portion 130 covers the side of each of the leads 111, wherein the metal paste MP is heated to form the solderable portion 130 by reflowing during the step S104, so that the solderable portion 130 is fixed on the surface of each of the leads 111.

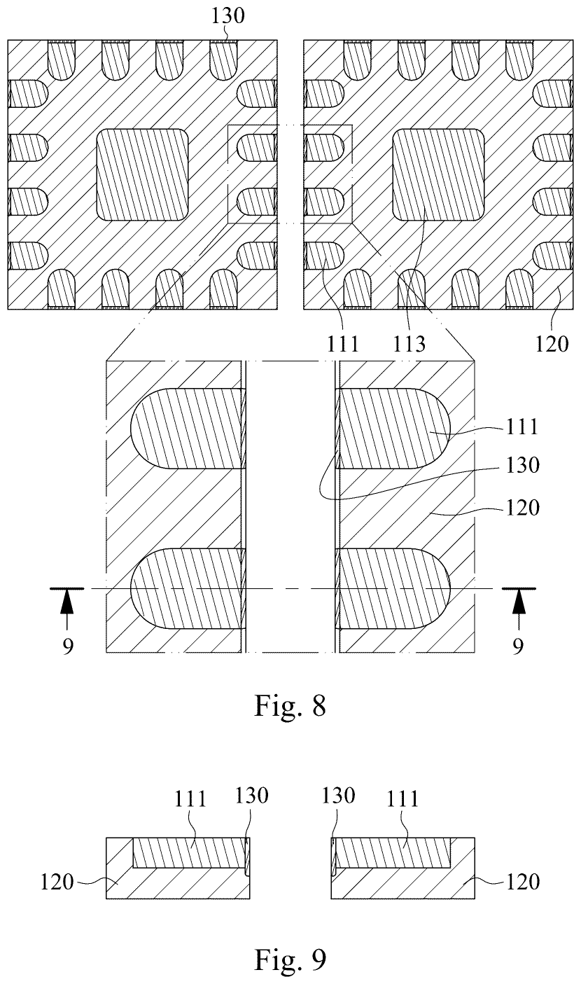

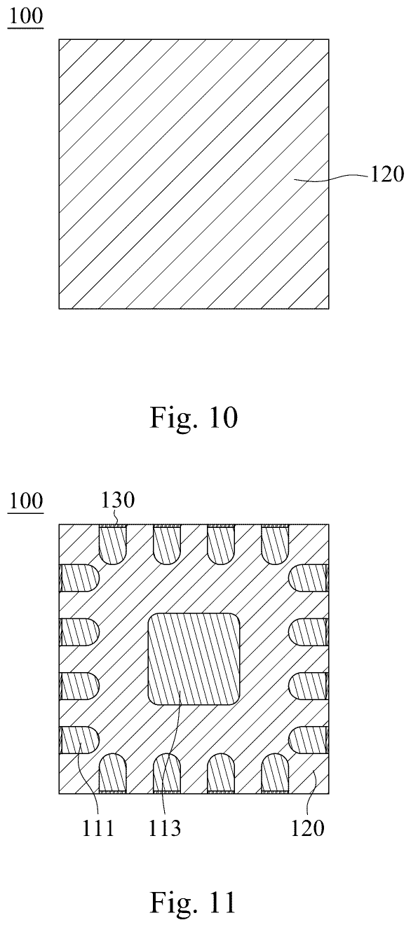

FIG. 8 is a schematic view of the step S105 according to the 1st example in FIG. 1. FIG. 9 is a cross-sectional schematic view of the package structure 100 along line 9-9 in FIG. 8. FIG. 10 is a front view of the package structure 100 according to the 1st example in FIG. 1. FIG. 11 is a back view of the package structure 100 according to the 1st example in FIG. 1. In FIGS. 1 and 8-11, the step S105 includes cutting the cutting streets 112 (labelled in FIG. 2) of the leadframe 110 to form the package structure 100, wherein the cutting streets 112 of the leadframe 110 can be cut via a blade, and a cutting width can be wider than or equal to a width of each of the cutting streets 112.

Moreover, a depth of the grooves S formed via the laser beam L during the step S102 is larger than a thickness of each of the leads 111, so that the solderable portion 130 can entirely cover the surface of each of the leads 111. The surface of each of the leads 111 excludes the copper-exposing surface during forming the package structure 100 at the step S105, so that the side wettable area of the package structure 100 can be increased, and the connecting strength between the package structure 100 and the circuit board can be further enhanced.

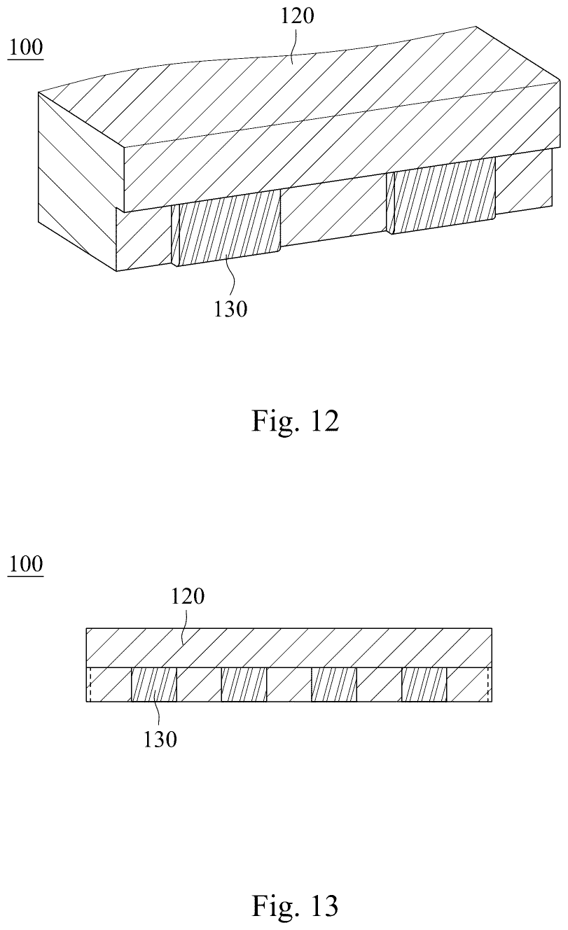

FIG. 12 is a partial schematic view of the package structure 100 according to the 1st example in FIG. 1. FIG. 13 is a side view of the package structure 100 according to the 1st example in FIG. 1. In FIGS. 10-13, the package structure 100 includes the leadframe 110, the semiconductor die, the plastic package material 120 and the solderable portion 130, wherein the plastic package material 120 is disposed on the leadframe 110. The leadframe 110 includes the die pad 113 and the leads 111, wherein the leads 111 are disposed around the die pad 113, the semiconductor die is disposed on the die pad 113 of the leadframe 110, and the solderable portion 130 covers a surface of each of the leads 111.

Therefore, the copper-exposing surface can be avoided forming on the surface of each of the leads 111 by entirely covering the surface of each of the leads 111 via the solderable portion 130, so that the side wettable area of the package structure 100 can be increased, and the board-level reliability can be further enhanced for widely applying to the automotive products. It should be mentioned that the automotive products need the high requirement of the board-level reliability of the package structure.

Moreover, the solderable portion 130 can be made of tin alloy. In particular, the package structure 100 can have the high flexibility in the selection of the material of the solderable portion 130, that is, the material of the solderable portion 130 can be flexibly selected according to the package requirement. Therefore, the package structure 100 can be suitable for different package requirements.

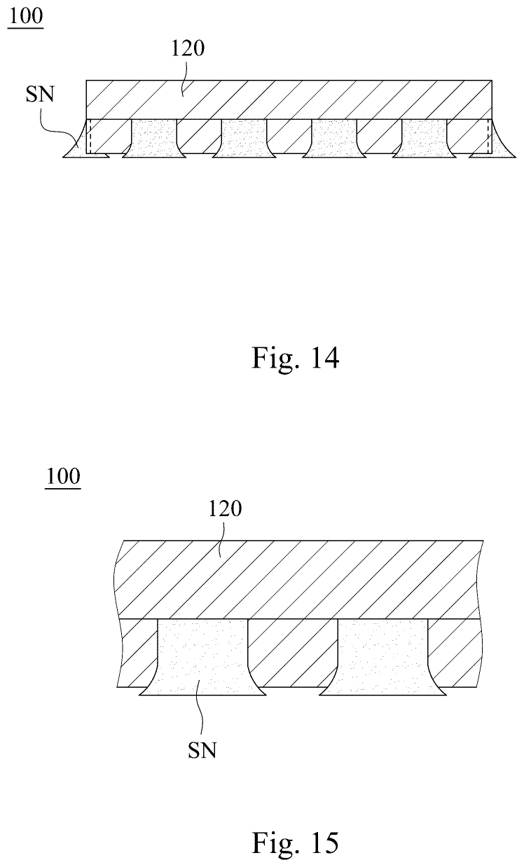

FIG. 14 is a side view of the package structure 100 after soldering according to the 1st example in FIG. 1. FIG. 15 is a partial side view of the package structure 100 after soldering according to the 1st example in FIG. 14. In FIGS. 14 and 15, when the package structure 100 is connected to the circuit board via a soldering portion SN, the soldering portion SN can be disposed on the wide range owing to the solderable portion 130 entirely covering the surface of each of the leads 111. In other words, the lateral of each of the leads 111 has the large range of the solderable area, so that the connecting strength between each of the leads 111 and the circuit board can be enhanced.

It should be mentioned that the thickness of the metal paste MP, the thickness of the solderable portion 130 and the width of the grooves S according to the 1st example are only configured to be the schematic view of the disposition relationship rather than the actual thickness and the actual width.

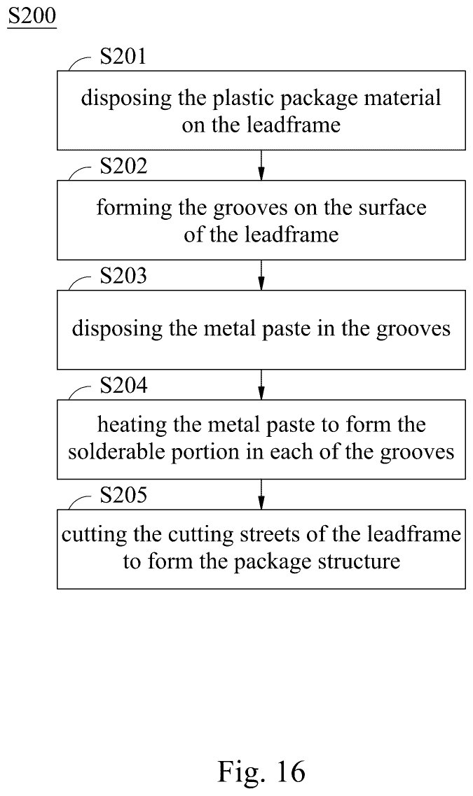

FIG. 16 is a step flow chart of a method of forming a package structure S200 according to the 2nd example of the present disclosure. In FIG. 16, the method of the package structure S200 includes steps S201, S202, S203, S204, S205.

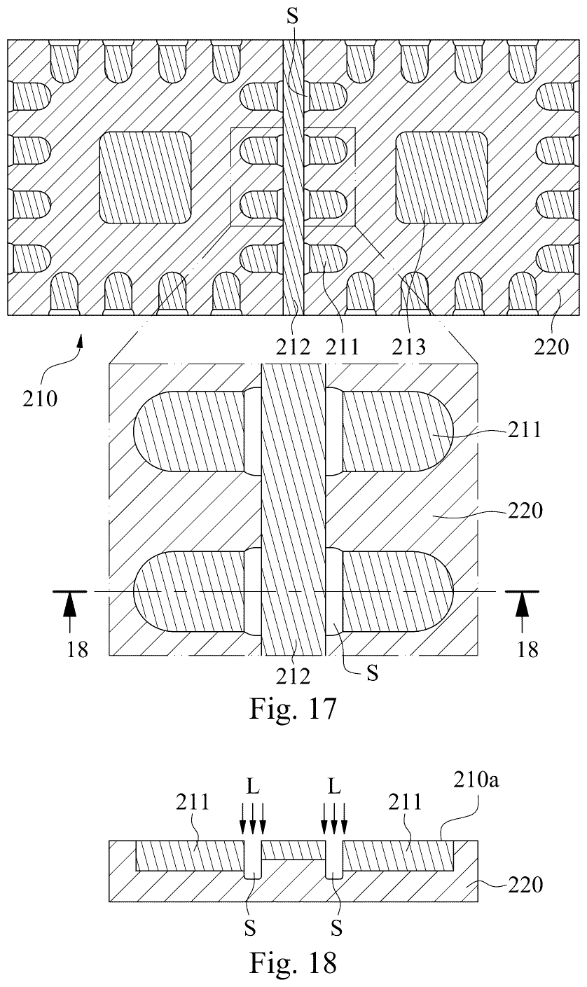

FIG. 17 is a schematic view of the steps S201, S202 according to the 2nd example in FIG. 16. FIG. 18 is a cross-sectional schematic view of the leadframe 210 along line 18-18 in FIG. 17. In FIGS. 16 to 18, the step S201 includes disposing a plastic package material 220 on the leadframe 210, and the step S202 includes forming a plurality of grooves S on a surface 210a of the leadframe 210, wherein the leadframe 210 includes a plurality of leads 211 and a plurality of cutting streets 212, and the grooves S are disposed on a side of each of the leads 211.

Moreover, the grooves S are formed on the surface 210a of the leadframe 210 via a laser beam L during the step S202, the grooves S are disposed between each of the leads 211 and each of the cutting streets 212, and a gap is located between each two of the grooves S, wherein the plastic package material 220 is located in the gap between the grooves S, and the laser beam L can be a dual-frequency Nd-YAG laser light source with wavelength of 532 nm, a UV nanosecond pulse or a picosecond laser.

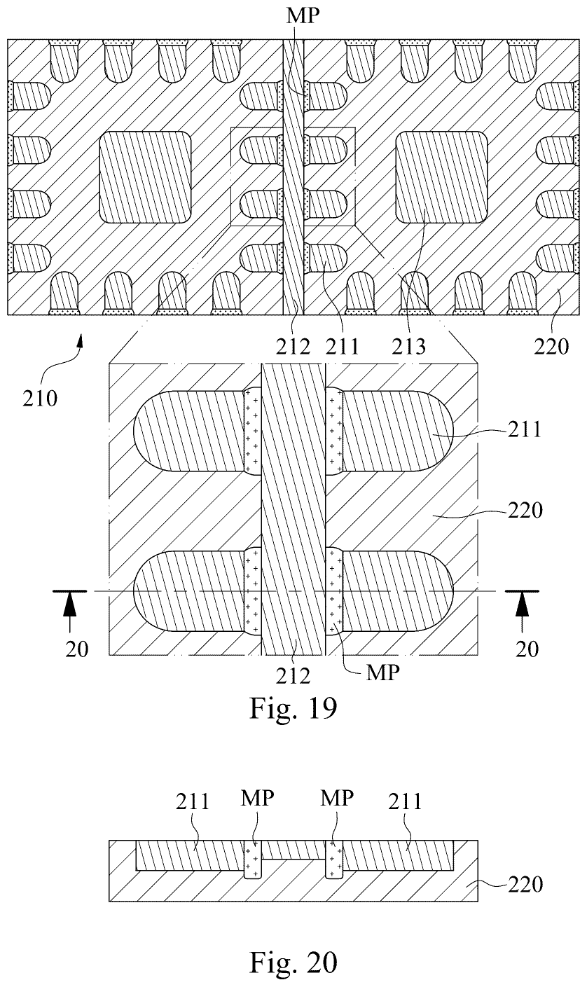

FIG. 19 is a schematic view of the step S203 according to the 2nd example in FIG. 16. FIG. 20 is a cross-sectional schematic view of the leadframe 210 along line 20-20 in FIG. 19. In FIGS. 16, 19 and 20, the step S203 includes disposing a metal paste MP in the grooves S, wherein the metal paste MP is directly disposed in each of the grooves S by setting the amount of the metal paste MP, and a volume of the metal paste MP is corresponding to a volume of each of the grooves S. In particular, the cost of manufacturing the corresponding printing mold can be reduced by setting the certain amount of the metal paste MP to dispose in each of the grooves S.

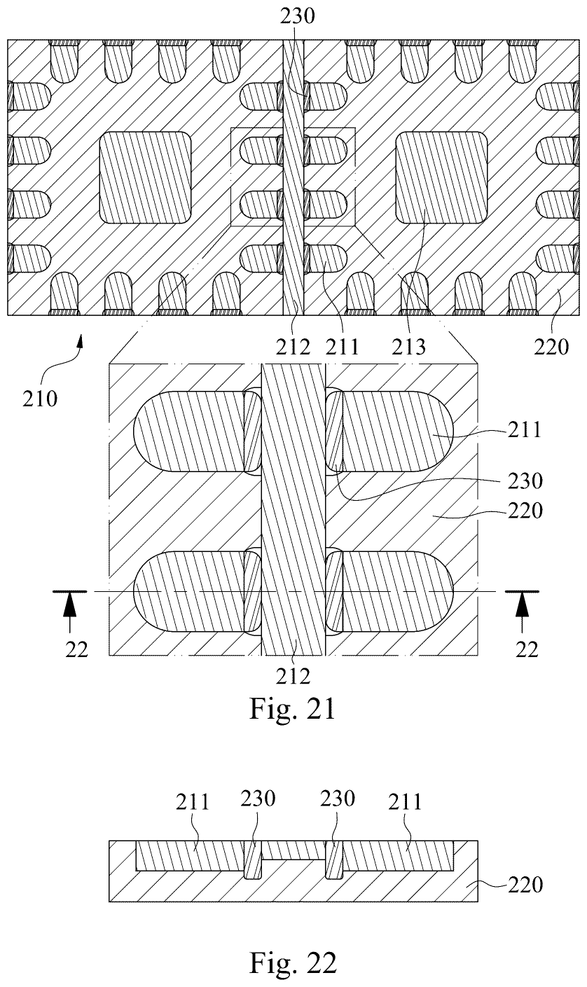

FIG. 21 is a schematic view of the step S204 according to the 2nd example in FIG. 16. FIG. 22 is a cross-sectional schematic view of the leadframe 210 along line 22-22 in FIG. 21. In FIGS. 16, 21 and 22, the step S204 includes heating the metal paste MP to form a solderable portion 230 in each of the grooves S, and the solderable portion 230 covers the side of each of the leads 211. In detail, a depth of each of the grooves S is larger than a thickness of each of the leads 211, and a width of each of the grooves S is slightly wider than a width of a side of each of the leads 211, and hence the solderable portion 230 can entirely cover the side of each of the leads 211.

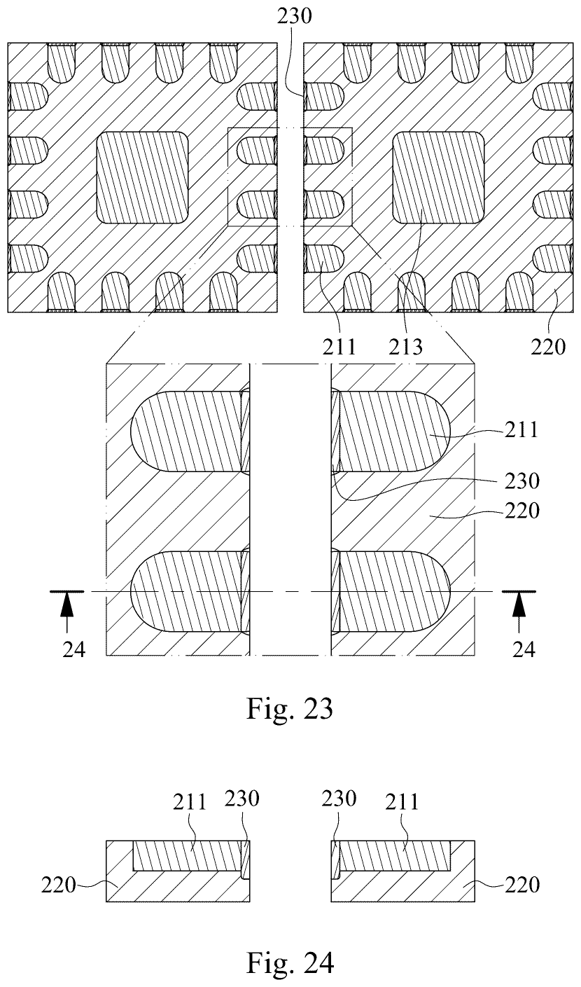

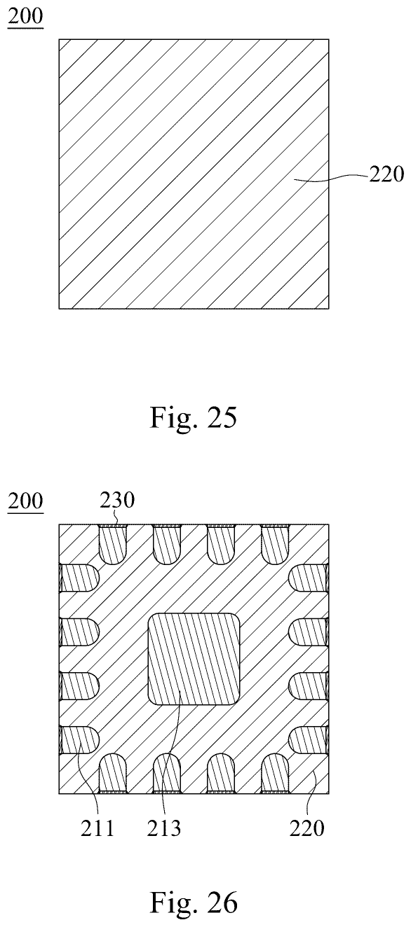

FIG. 23 is a schematic view of the step S205 according to the 2nd example in FIG. 16. FIG. 24 is a cross-sectional schematic view of the package structure 200 along line 24-24 in FIG. 23. FIG. 25 is a front view of the package structure 200 according to the 2nd example in FIG. 16. FIG. 26 is a back view of the package structure 200 according to the 2nd example in FIG. 16. In FIGS. 16 and 23-26, the step S205 includes cutting the cutting streets 212 (labelled in FIG. 17) of the leadframe 210 to form the package structure 200.

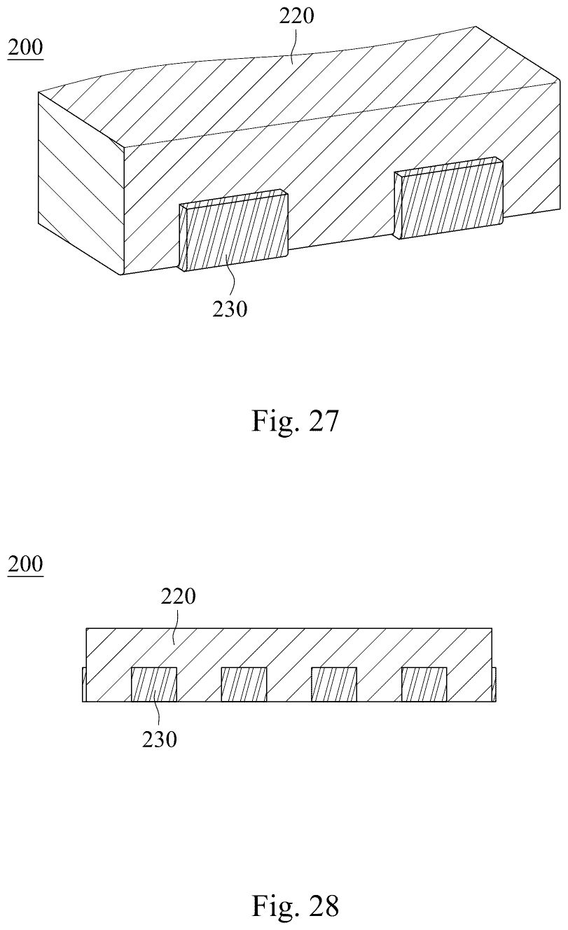

FIG. 27 is a partial schematic view of the package structure 200 according to the 2nd example in FIG. 16. FIG. 28 is a side view of the package structure 200 according to the 2nd example in FIG. 16. In FIGS. 25 to 28, the package structure 200 includes the leadframe 210, the semiconductor die, the plastic package material 220 and the solderable portion 230, wherein the plastic package material 220 is disposed on the leadframe 210. The leadframe 210 includes the die pad 213 and the leads 211, wherein the leads 211 are disposed around the die pad 213, the semiconductor die is disposed on the die pad 213 of the leadframe 210, and the solderable portion 230 covers a surface of each of the leads 211.

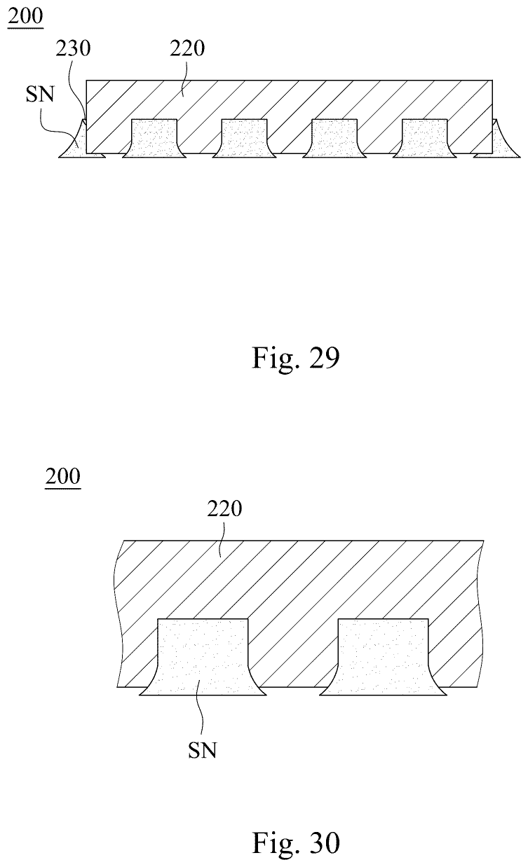

FIG. 29 is a side view of the package structure 200 after soldering according to the 2nd example in FIG. 16. FIG. 30 is a partial side view of the package structure 200 after soldering according to the 2nd example in FIG. 29. In FIGS. 29 and 30, when the package structure 200 is connected to the circuit board via a soldering portion SN, the soldering portion SN can be disposed on the wide range owing to the solderable portion 230 entirely covering the surface of each of the leads 211. In other words, the lateral of each of the leads 211 has the large range of the solderable area, so that the connecting strength between each of the leads 211 and the circuit board can be enhanced.

It should be mentioned that the thickness of the metal paste MP, the thickness of the solderable portion 230 and the width of the grooves S according to the 2nd example are only configured to be the schematic view of the disposition relationship rather than the actual thickness and the actual width.

Further, all of other structures and dispositions according to the 2nd example are the same as the structures and the dispositions according to the 1st example, and will not be described again herein.

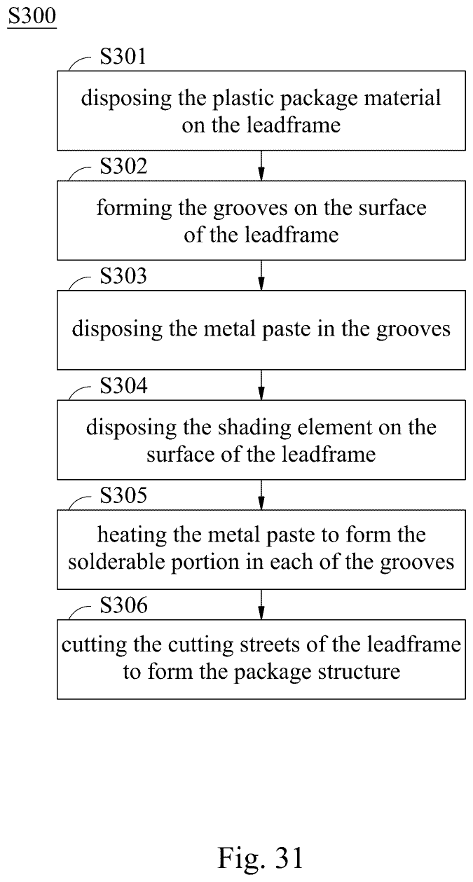

FIG. 31 is a step flow chart of a method of forming a package structure S300 according to the 3rd example of the present disclosure. In FIG. 31, the method of the package structure S300 includes steps S301, S302, S303, S304, S305, S306.

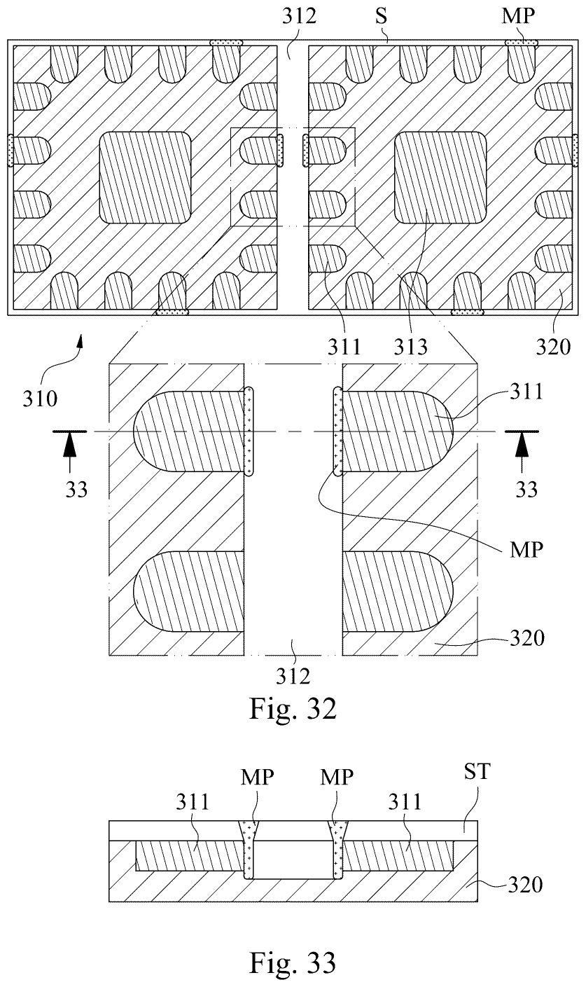

FIG. 32 is a schematic view of the steps S301, S302, S303 according to the 3rd example in FIG. 31. FIG. 33 is a cross-sectional schematic view of the leadframe 310 along line 33-33 in FIG. 32. In FIGS. 31 to 33, the step S301 includes disposing a plastic package material 320 on the leadframe 310, the step S302 includes forming at least one groove S on a surface of the leadframe 310, and the step S303 includes disposing a metal paste MP in the groove S, wherein the leadframe 310 includes a plurality of leads 311 and a plurality of cutting streets 312, the groove S is disposed on a side of at least one of the leads 311, and the metal paste MP can be disposed in the grooves S via a mold ST.

Furthermore, the groove S according to the 3rd example is plural, the grooves S are located on a side of each of the partial of the leads 311, and the metal paste MP is selectively disposed on the side of each of the partial of the leads 311, wherein the aforementioned leads 311 are the ground connection, and a number of the aforementioned leads 311 is four and located around the leadframe 310, respectively, but the number is not limited thereto.

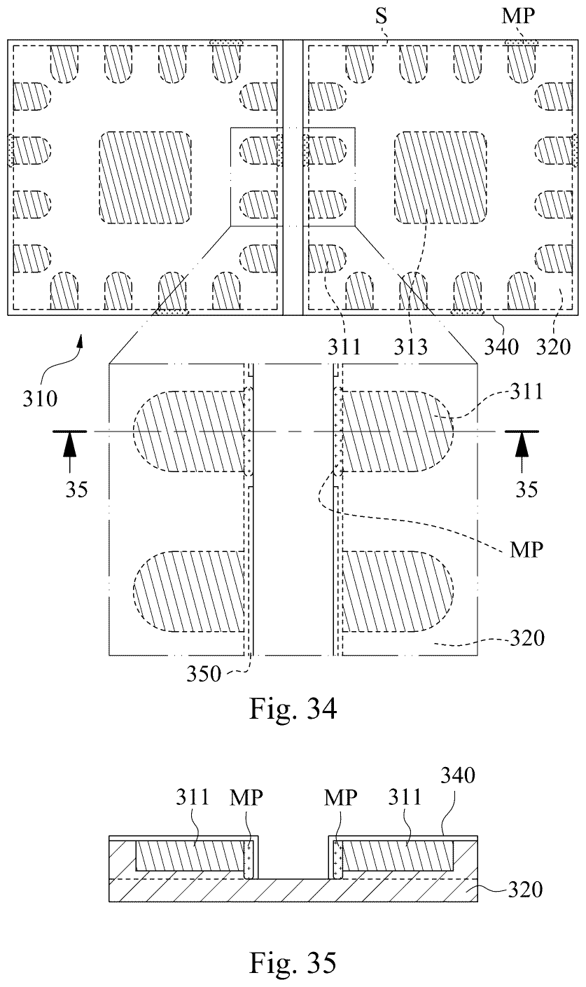

FIG. 34 is a schematic view of the step S304 according to the 3rd example in FIG. 31. FIG. 35 is a cross-sectional schematic view of the leadframe 310 along line 35-35 in FIG. 34. In FIGS. 31, 34 and 35, the step S304 includes disposing a shading element 340 on the surface of the leadframe 310, wherein the shading element 340 and the grooves S are located on the same side. By disposing the shading element 340 during the package process, the following assembling process can be facilitated. In particular, the shading element 340 is physically contacted with the metal paste MP, wherein the location of the metal paste MP can be configured to control the connection between the partial of the leads 311 and the shading element 340.

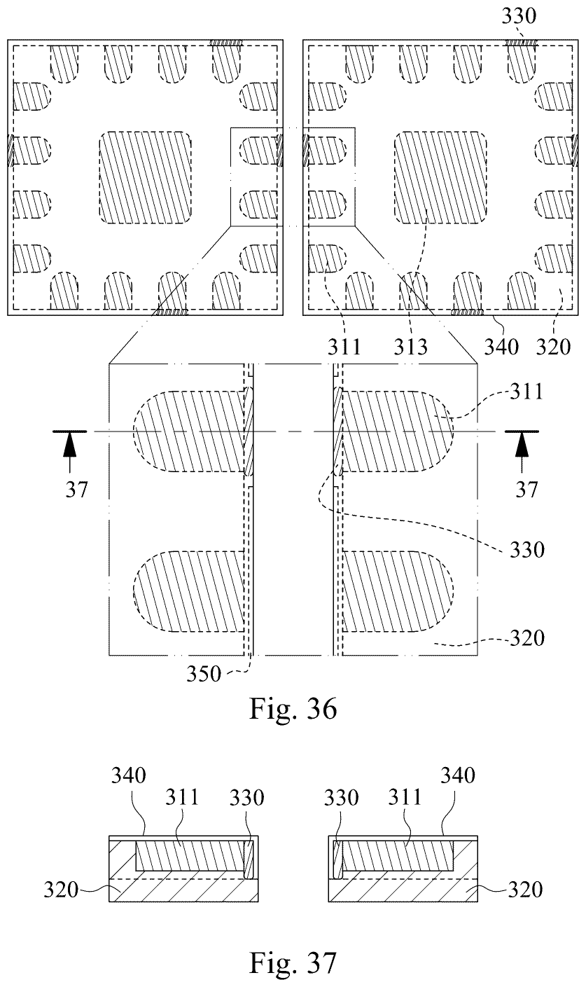

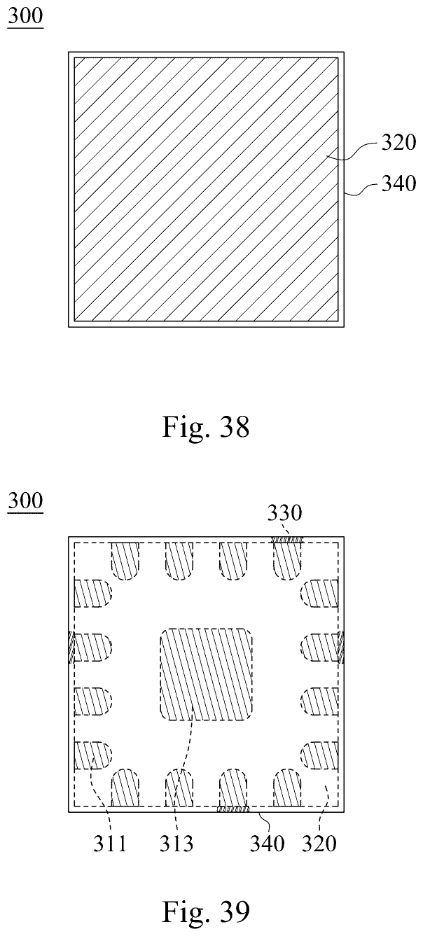

FIG. 36 is a schematic view of the steps S305, S306 according to the 3rd example in FIG. 31. FIG. 37 is a cross-sectional schematic view of the package structure 300 along line 37-37 in FIG. 36. FIG. 38 is a front view of the package structure 300 according to the 3rd example in FIG. 31. FIG. 39 is a back view of the package structure 300 according to the 3rd example in FIG. 31. In FIGS. 31 and 36-39, the step S305 includes heating the metal paste MP to form a solderable portion 330 in each of the grooves S, and the step S306 includes cutting the cutting streets 312 (labelled in FIG. 32) of the leadframe 310 to form the package structure 300, wherein the solderable portion 330 covers the side of at least one of the leads 311. Further, the solderable portion 330 covers the sides of four of the leads 311, respectively.

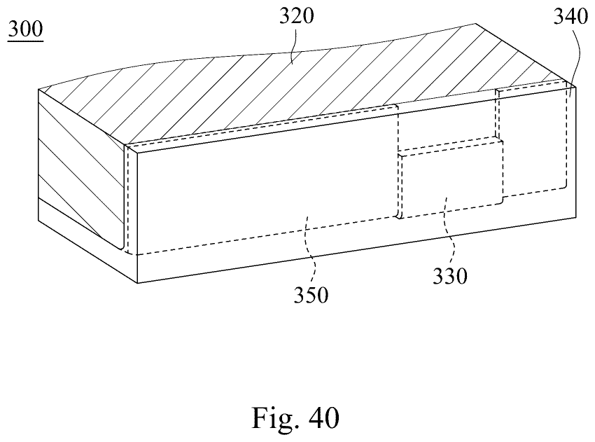

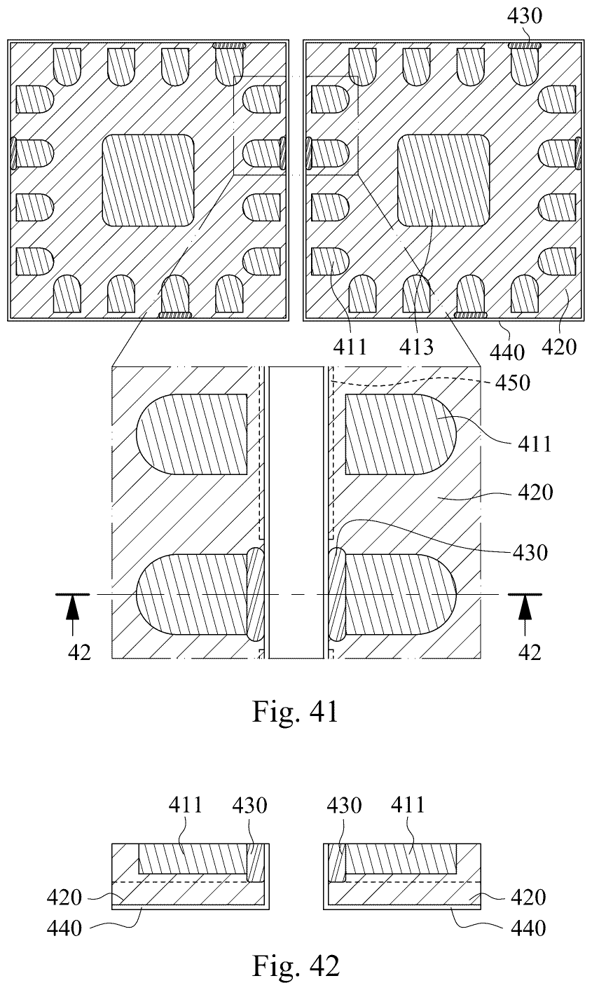

FIG. 40 is a partial schematic view of the package structure 300 according to the 3rd example in FIG. 31. In FIGS. 38 to 40, the package structure 300 includes the leadframe 310, the semiconductor die, the plastic package material 320, the solderable portion 330 and the shading element 340, wherein the plastic package material 320 is disposed on the leadframe 310, and the shading element 340 is disposed on the surface of the leadframe 310. The leadframe 310 includes the die pad 313 and the leads 311, wherein the leads 311 are disposed around the die pad 313, the semiconductor die is disposed on the die pad 313 of the leadframe 310, and the solderable portion 330 covers a surface of at least one of the leads 311. Further, the solderable portion 330 covers the surfaces of four of the leads 311, respectively.

In FIGS. 34, 36 and 40, the package structure 300 can further include an insulating layer 350, wherein the insulating layer 350 is disposed on a side of at least another one of the leads 311, and the insulating layer 350 can be contacted with the side of at least another one of the leads 311. Or, a gap is located between the insulating layer 350 and the side of at least another one of the leads 311. In particular, the insulating layer 350 can be an element or a coating located on an inner surface of the shading element 340, and the insulating layer 350 is selectively disposed on the side of the side of at least another one of the leads 311. In detail, if the metal paste MP is selectively disposed on the side of the leads 311, the insulating layer 350 is not disposed on the side of the aforementioned leads 311. It should be mentioned that another leads 311 are not connected except for the partial of the leads 311 which are the ground connection, and hence the insulating layer 350 is disposed on the side of the leads 311 without the metal paste MP. Therefore, the insulating layer 350 is configured to isolate the side of the leads 311 without the metal paste MP from the shading element 340 so as to avoid the condition of the welding short circuit.

Moreover, when the width between the leads 311 without the metal paste MP and the shading element 340 is wide enough, the package structure 300 can selectively include the insulating layer 350.

In detail, the shading element 340 can be an electromagnetic interference shielding element, but the present disclosure is not limited thereto.

It should be mentioned that the thickness of the metal paste MP, the thickness of the solderable portion 330, the width of the grooves S, the thickness of the shading element 340 and the thickness of the insulating layer 350 according to the 3rd example are only configured to be the schematic view of the disposition relationship rather than the actual thickness and the actual width.

Further, all of other structures and dispositions according to the 3rd example are the same as the structures and the dispositions according to the 1st example, and will not be described again herein.

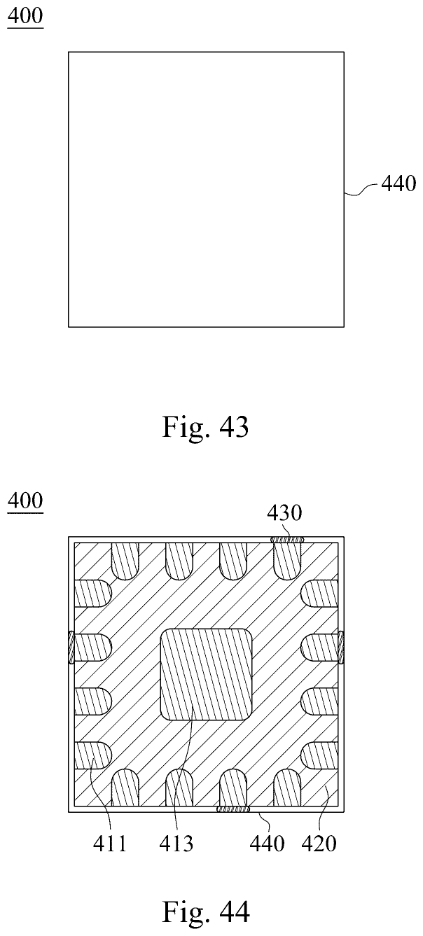

FIG. 41 is a partial schematic view of a method of forming a package structure according to the 4th example of the present disclosure. FIG. 42 is a cross-sectional schematic view of a leadframe along line 42-42 in FIG. 41. In FIGS. 41 and 42, the method of the package structure (its reference numeral is omitted) includes steps, wherein the steps include disposing a plastic package material 420 on the leadframe (its reference numeral is omitted), forming a plurality of grooves (their reference numerals are omitted) on a surface of the leadframe, disposing a metal paste (not shown) in the grooves, heating the metal paste to form a solderable portion 430 in each of the grooves, and cutting the cutting streets (their reference numerals are omitted) of the leadframe to form the package structure 400 (labelled in FIG. 43), wherein the leadframe includes a plurality of leads 411 and a plurality of cutting streets, the grooves are disposed on sides of four of the leads 411, respectively, and the solderable portion 430 covers the sides of four of the leads 411, respectively. Furthermore, the grooves are selectively located on the side of each of the partial of the leads 411, and the method of forming the grooves according to the 4th example can be referred to the 2nd example, wherein the aforementioned leads 411 are the ground connection. The metal paste can be directly disposed in each of the grooves, and a volume of the metal paste is corresponding to a volume of each of the grooves.

Further, the method of the package structure can further include a step including disposing a shading element 440 on a surface of the plastic package material 420. Moreover, the disposition of the shading element 440 can proceed after forming from the metal paste to the solderable portion 430 and cutting the cutting streets of the leadframe, but the present disclosure is not limited thereto.

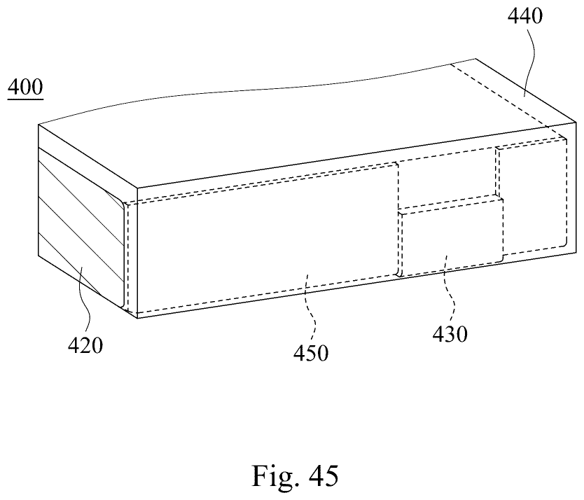

FIG. 43 is a front view of the package structure 400 according to the 4th example in FIG. 41. FIG. 44 is a back view of the package structure 400 according to the 4th example in FIG. 41. FIG. 45 is a partial schematic view of the package structure 400 according to the 4th example in FIG. 41. In FIGS. 43 to 45, the package structure 400 includes the leadframe, the semiconductor die, the plastic package material 420, the solderable portion 430, the shading element 440 and an insulating layer 450, wherein the plastic package material 420 is disposed on the leadframe, and the shading element 440 is disposed on the surface of the plastic package material 420. The leadframe includes the die pad 413 and the leads 411, wherein the leads 411 are disposed around the die pad 413, the semiconductor die is disposed on the die pad 413 of the leadframe, the solderable portion 430 covers surfaces of four of the leads 411, respectively, and the insulating layer 450 is disposed on a side of at least another one of the leads 411.

It should be mentioned that the difference between the 4th example and the 3rd example is disposing the shading element on a surface of the plastic package material or the surface of the leadframe, and the thickness of the solderable portion 430, the thickness of the shading element 440 and the thickness of the insulating layer 450 according to the 4th example are only configured to be the schematic view of the disposition relationship rather than the actual thickness.

Further, all of other structures and dispositions according to the 4th example are the same as the structures and the dispositions according to the 1st example and the 3rd example, and will not be described again herein.

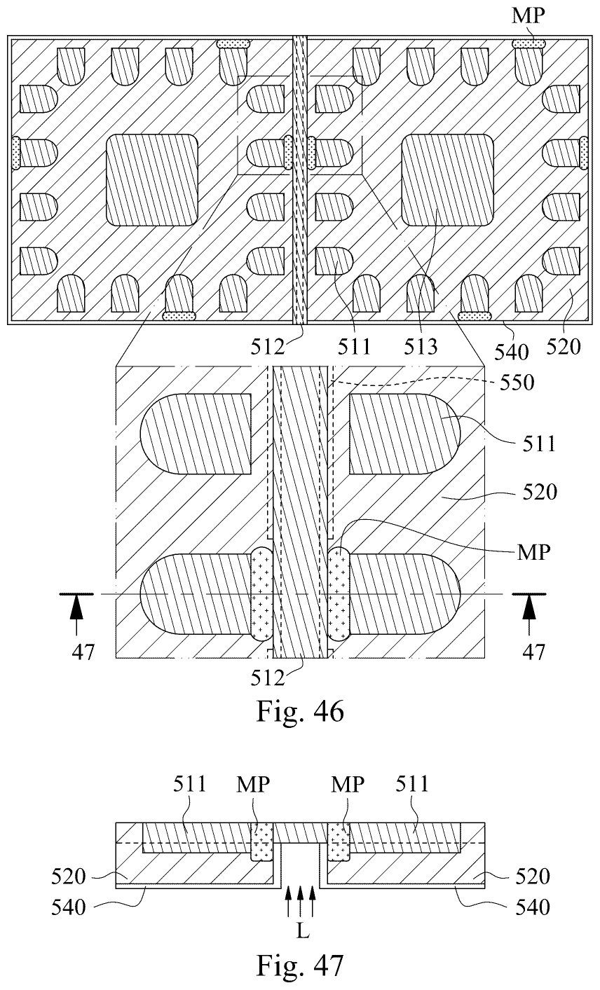

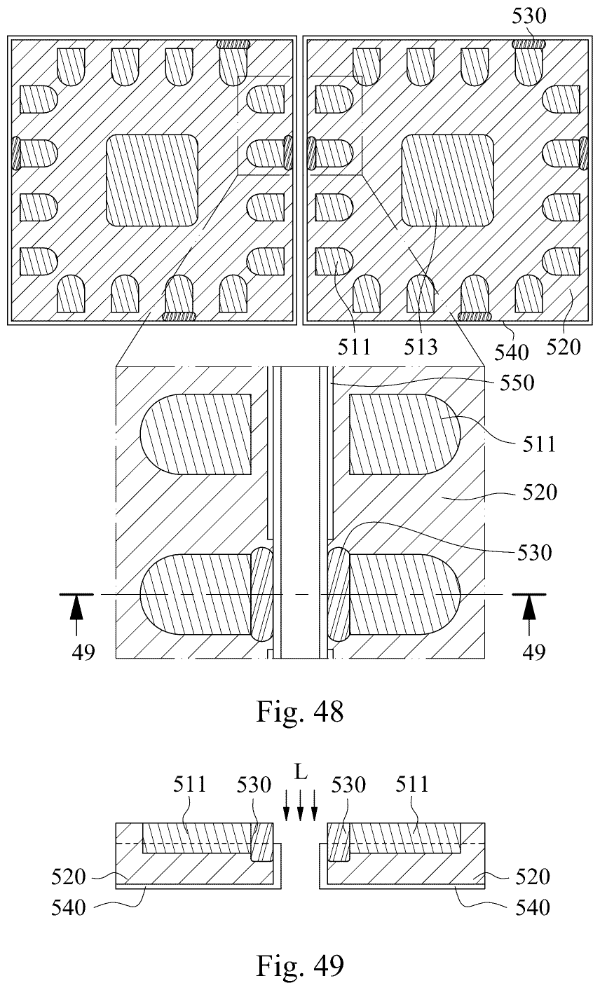

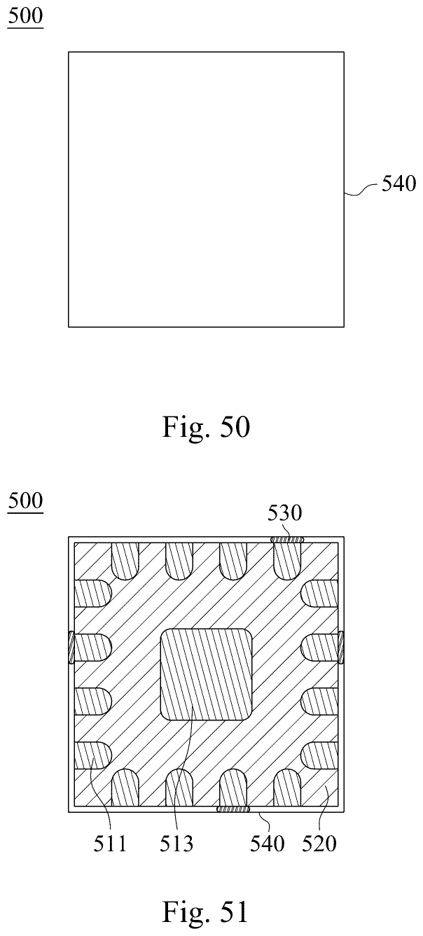

FIG. 46 is a partial schematic view of a method of forming a package structure according to the 5th example of the present disclosure. FIG. 47 is a cross-sectional schematic view of a leadframe along line 47-47 in FIG. 46. FIG. 48 is another partial schematic view of the method of the package structure according to the 5th example in FIG. 46. FIG. 49 is a cross-sectional schematic view of the leadframe along line 49-49 in FIG. 48. In FIGS. 46 to 49, the method of the package structure (its reference numeral is omitted) includes steps, wherein the steps include disposing a plastic package material 520 on the leadframe (its reference numeral is omitted), forming a plurality of grooves (their reference numerals are omitted) on a surface of the leadframe, disposing a metal paste MP in the grooves, heating the metal paste MP to form a solderable portion 530 in each of the grooves, and cutting the cutting streets 512 of the leadframe to form the package structure 500 (labelled in FIG. 50), wherein the leadframe includes a plurality of leads 511, the grooves are disposed on sides of four of the leads 511, respectively, and the solderable portion 530 covers the sides of four of the leads 511, respectively. Furthermore, the grooves are selectively located on the side of each of the partial of the leads 511, and the method of forming the grooves according to the 5th example can be referred to the 2nd example, wherein the aforementioned leads 511 are the ground connection.

Further, the method of the package structure can further include a step including disposing a shading element 540 on a surface of the plastic package material 520. Moreover, the grooves are formed on the plastic package material 520 located on the cutting streets 512 via a laser beam L or a blade, the shading element 540 is disposed on the surface of the plastic package material 520, the metal paste MP is formed into the solderable portion 530, and then the remain of the plastic package material 520 located on the cutting streets 512 and the cutting streets 512 are removed via the laser beam L or the blade to form the package structure 500, but the present disclosure is not limited thereto.

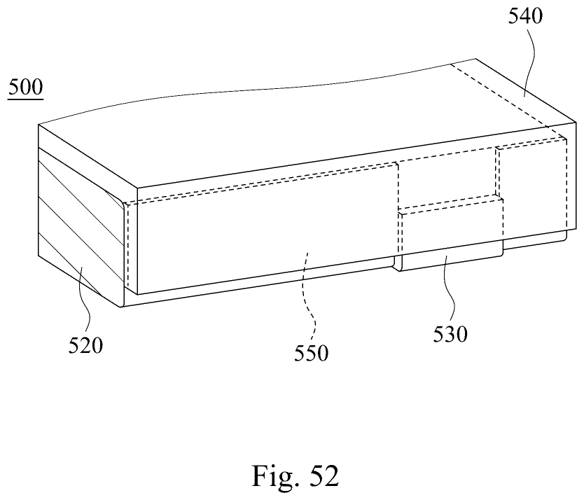

FIG. 50 is a front view of the package structure 500 according to the 5th example in FIG. 46. FIG. 51 is a back view of the package structure 500 according to the 5th example in FIG. 46. FIG. 52 is a partial schematic view of the package structure 500 according to the 5th example in FIG. 46. In FIGS. 50-52, the package structure 500 includes the leadframe, the semiconductor die, the plastic package material 520, the solderable portion 530, the shading element 540 and an insulating layer 550, wherein the plastic package material 520 is disposed on the leadframe, and the shading element 540 is disposed on the surface of the plastic package material 520. The leadframe includes the die pad 513 and the leads 511, wherein the leads 511 are disposed around the die pad 513, the semiconductor die is disposed on the die pad 513 of the leadframe, the solderable portion 530 covers surfaces of four of the leads 511, respectively, and the insulating layer 550 is disposed on a side of at least another one of the leads 511.

According to the 5th example, the shading element 540 is configured to cover a half height of the solderable portion 530, and a height of the insulating layer 550 and a height of the shading element 540 are the same.

It should be mentioned that difference between the 5th example and the 4th example is the range of the shading element covering the solderable portion, and the thickness of the metal paste MP, the thickness of the solderable portion 530, the thickness of the shading element 540 and the thickness of the insulating layer 550 according to the 5th example are only configured to be the schematic view of the disposition relationship rather than the actual thickness.

Further, all of other structures and dispositions according to the 5th example are the same as the structures and the dispositions according to the 1st example, the 3rd example and the 4th example, and will not be described again herein.

In summary, the copper-exposing surface can be avoided forming on the surface of each of the leads by entirely covering the surface of each of the leads via the solderable portion, so that the side wettable area of the package structure can be increased. Further, the connecting strength between the package structure and the circuit board can be enhanced, and the board-level reliability of the package structure can be further promoted for widely applying to the automotive products. Moreover, the shading element can be further disposed so as to facilitate the following assembling process.

The foregoing description, for purpose of explanation, has been described with reference to specific examples. It is to be noted that Tables show different data of the different examples; however, the data of the different examples are obtained from experiments. The examples were chosen and described in order to best explain the principles of the disclosure and its practical applications, to thereby enable others skilled in the art to best utilize the disclosure and various examples with various modifications as are suited to the particular use contemplated. The examples depicted above and the appended drawings are exemplary and are not intended to be exhaustive or to limit the scope of the present disclosure to the precise forms disclosed. Many modifications and variations are possible in view of the above teachings.

What is claimed is:

1. A method of forming a package structure, comprising:
forming a plurality of grooves on a surface of a leadframe, wherein the leadframe comprises a plurality of leads, and the grooves are disposed on a side of each of the leads;
disposing a metal paste in the grooves;
heating the metal paste to form a solderable portion in each of the grooves; and
cutting a plurality of cutting streets of the leadframe to form the package structure;
wherein the solderable portion covers the side of each of the leads.

2. The method of forming the package structure of claim 1, further comprising:
disposing a plastic package material on the leadframe.

3. The method of forming the package structure of claim 1, wherein the grooves are disposed between each of the leads and each of the cutting streets.

4. The method of forming the package structure of claim 1, wherein the grooves are formed on the surface of the leadframe via a laser beam.

5. The method of forming the package structure of claim 1, wherein the grooves are connected to each other.

6. The method of forming the package structure of claim 1, wherein a gap is located between each two of the grooves.

7. The method of forming the package structure of claim 6, wherein the metal paste is directly disposed in each of the grooves, and a volume of the metal paste is corresponding to a volume of each of the grooves.

8. The method of forming the package structure of claim 1, wherein the metal paste is further disposed on a surface of a die pad of the leadframe.

9. The method of forming the package structure of claim 1, wherein a width of each of the grooves is between 0.1 mm and 10 mm.

10. The method of forming the package structure of claim 1, wherein the metal paste is disposed in the grooves via a mold.

11. A method of forming a package structure, comprising:
forming at least one groove on a surface of a leadframe, wherein the leadframe comprises a plurality of leads, and the at least one groove is disposed on a side of at least one of the leads;
disposing a metal paste in the at least one groove;
heating the metal paste to form a solderable portion in the at least one groove; and
cutting a plurality of cutting streets of the leadframe to form the package structure;
wherein the solderable portion covers the side of the at least one of the leads.

12. The method of forming the package structure of claim 11, further comprising:
disposing a plastic package material on the leadframe; and
disposing a shading element on a surface of the plastic package material or the surface of the leadframe.

13. The method of forming the package structure of claim 11, wherein the metal paste is directly disposed in the at least one groove, and a volume of the metal paste is corresponding to a volume of the at least one groove.

14. The method of forming the package structure of claim 11, wherein the metal paste is disposed in the at least one groove via a mold.

15. A package structure, comprising:
a leadframe, comprising:
a die pad; and
a plurality of leads disposed around the die pad;
a semiconductor die disposed on the die pad of the leadframe;
a plastic package material disposed on the leadframe; and
a solderable portion covering a surface of at least one of the leads.

16. The package structure of claim 15, further comprising:
a shading element disposed on a surface of the plastic package material or a surface of the leadframe.

17. The package structure of claim 16, wherein the shading element is an electromagnetic interference shielding element.

18. The package structure of claim 16, further comprising:
an insulating layer disposed on a side of at least another one of the leads.

19. The package structure of claim 15, the solderable portion is made of tin alloy.

20. The package structure of claim 15, wherein the solderable portion covers the surface of each of the leads.
